(19) United States
(12) Patent Application Publication
(10) Pub. No.: US 2026/0130160 A1
(43) Pub. Date: May 7, 2026

(54) BONDING DEVICE

(71) Applicant: Samsung Display Co., Ltd., Yongin-si (KR)

(72) Inventors: TAEYOUNG PARK, Yongin-si (KR); BYUNG-MOO KIM, Yongin-si (KR); DONGHO PARK, Yongin-si (KR); JUN-HEE LEE, Yongin-si (KR); CHANG-OOK LEE, Yongin-si (KR); Junghyeok LIM, Yongin-si (KR); Jaeheung CHO, Yongin-si (KR)

(73) Assignee: Samsung Display Co., Ltd., Yongin-si (KR)

(21) Appl. No.: 19/361,363

(22) Filed: Oct. 17, 2025

(30) Foreign Application Priority Data
Nov. 5, 2024 (KR) 10-2024-0155468

(51) Int. Cl. H01L 21/67; H01L 21/683

(52) U.S. Cl. CPC H10P 72/0438; H10P 72/72

(57) ABSTRACT

Provided is a bonding device including a lower electrostatic chuck, an upper electrostatic chuck disposed above the lower electrostatic chuck, an elastic part disposed above the upper electrostatic chuck, a first shaft disposed on the upper electrostatic chuck and disposed in a space which is defined inside the elastic part, a first plate disposed on the first shaft and the elastic part, a bracket disposed on the first plate, a first cylinder disposed on the bracket, a guide rod disposed on the first plate, and a second cylinder disposed adjacent to the guide rod in a horizontal direction and connected to an upper end portion of the guide rod.

### CROSS-REFERENCE TO RELATED APPLICATION(S)

This patent application claims priority to and benefits of Korean Patent Application No. 10-2024-0155468 under 35 U.S.C. § 119, filed on Nov. 5, 2024, the entire contents of which are incorporated herein by reference.

### BACKGROUND

The disclosure herein relates to a bonding device.

An electronic apparatus which provides images to users, such as a smartphone, a digital camera, a laptop computer, a navigation system, and a smart television, includes a display device for displaying the images. The display device generates an image and provides the image to the user through a display screen.

Recently, with the technological development for the display device, various types of display devices are being developed. For example, a display device, which is capable of displaying an image not only on a front surface of the display device, but also on a rear surface and a side surface of the display device, is being developed.

A display device includes a display panel which displays an image and a window which is disposed on the display panel so as to protect the display panel. The window may be bonded to an upper surface of the display panel by using a bonding device.

### SUMMARY

The disclosure provides a bonding device capable of preventing bonding failure between a display module and a window.

However, embodiments are not limited to those set forth herein. The above and other embodiments will become more apparent to one of ordinary skill in the art to which the disclosure pertains by referencing the detailed description of the disclosure given below.

An embodiment provides a bonding device including: a lower electrostatic chuck; an upper electrostatic chuck disposed above the lower electrostatic chuck; an elastic part disposed above the upper electrostatic chuck; a first shaft disposed on the upper electrostatic chuck and disposed in a space which is defined inside the elastic part; a first plate disposed on the first shaft and the elastic part; a bracket disposed on the first plate; a first cylinder disposed on the bracket; a guide rod disposed on the first plate; and a second cylinder disposed adjacent to the guide rod in a horizontal direction and connected to an upper end portion of the guide rod.

In an embodiment, the bonding device may further include a support plate disposed above the first plate and including a hole, wherein the first cylinder may be disposed on the support plate and extend toward the bracket, the second cylinder may be disposed on the support plate, and the guide rod may extend above the support plate through the hole of the support plate.

In an embodiment, the first cylinder may include: a first body disposed on the support plate; and a first movable rod connected to a lower part of the first body, extending below the support plate, and disposed on the bracket, and the first movable rod may be movable vertically.

In an embodiment, the first movable rod may be separated from the bracket and be in contact with an upper surface of the bracket.

In an embodiment, the bonding device may further include: a support pillar adjacent to a side of the support plate; and a vertical moving part connected to a side of the support plate and the support pillar and moving in a vertical direction.

In an embodiment, in case that process objects disposed on an upper surface of the lower electrostatic chuck and a lower surface of the upper electrostatic chuck are bonded to each other, the vertical moving part may be movable in a downward direction by a first distance, and the first movable rod may be movable toward the first body by a second distance shorter than the first distance.

In an embodiment, the second cylinder may include: a second body disposed on the support plate; and a second movable rod connected to an upper part of the second body, extending upward, and connected to an upper end portion of the guide rod, and the second movable rod may be movable vertically.

In an embodiment, the bonding device may further include a connection bar connected to the upper end portion of the guide rod and an upper end portion of the second movable rod.

In an embodiment, the first cylinder may be provided in plurality, the second cylinder may be provided in plurality, the plurality of first cylinders may be arranged in a first direction, and the plurality of second cylinders may be spaced apart from the plurality of first cylinders in a second direction intersecting the first direction, and be arranged in the first direction.

In an embodiment, the guide rod may be provided in plurality, the plurality of guide rods may be arranged in the first direction and be spaced apart from the plurality of first cylinders in the second direction, and the plurality of second cylinders may be disposed between the plurality of guide rods.

In an embodiment, the bonding device may further include: a second shaft disposed under the lower electrostatic chuck; and a second plate disposed under the second shaft.

In an embodiment, an upper surface of the lower electrostatic chuck may have a concave curved surface, and a lower surface of the upper electrostatic chuck may have a convex curved surface.

In an embodiment, a display module may be disposed on the upper surface of the lower electrostatic chuck, and a window may be disposed on the lower surface of the upper electrostatic chuck.

In an embodiment, the elastic part may provide an elastic force to the first plate and the lower electrostatic chuck in a vertical direction.

In an embodiment, a bonding device includes: a lower electrostatic chuck; an upper electrostatic chuck disposed above the lower electrostatic chuck; an elastic part disposed above the upper electrostatic chuck; a first shaft disposed on the upper electrostatic chuck and disposed in a space which is defined inside the elastic part; a first plate disposed on the first shaft and the elastic part; a bracket disposed on the first plate; a first cylinder including a first body disposed on the bracket, and a first movable rod extending from the first body toward the bracket and being in contact with the bracket; a guide rod disposed on the first plate; and a second cylinder disposed adjacent to the guide rod in a horizontal direction and connected to an upper end portion of the guide rod.

In an embodiment, the first movable rod may be separated from the bracket and be in contact with an upper surface of the bracket.

In an embodiment, the bonding device may further include a support plate disposed above the first plate, wherein the second cylinder may include a second body disposed on the support plate, and a second movable rod connected to an upper part of the second body and extending upward, and connected to an upper end portion of the guide rod, and the second movable rod may be movable vertically.

In an embodiment, a bonding device includes: a lower electrostatic chuck; an upper electrostatic chuck disposed above the lower electrostatic chuck; an elastic part disposed above the upper electrostatic chuck; a first shaft disposed on the upper electrostatic chuck and disposed in a space which is defined inside the elastic part; a first plate disposed on the first shaft and the elastic part; a bracket disposed on the first plate; a first cylinder disposed on the bracket; a guide rod disposed on the first plate; a second cylinder disposed adjacent to the guide rod in a horizontal direction; and a connection bar connected to an upper end portion of the guide rod and an upper end portion of the second cylinder.

### BRIEF DESCRIPTION OF THE DRAWINGS

The accompanying drawings are included to provide a further understanding of the invention, and are incorporated in and constitute a part of this specification. The drawings illustrate embodiments and, together with the description, serve to explain principles of the invention. In the drawings:

FIG. 1 is a schematic view illustrating an automobile interior within which a display device manufactured by a bonding device according to an embodiment is disposed;

FIG. 2 is a schematic plan view of the display device illustrated in FIG. 1;

FIG. 3 is a schematic cross-sectional view of a display module and a window of a display device;

FIG. 4 is a schematic cross-sectional view illustrating the display module illustrated in FIG. 3;

FIG. 5 is a schematic cross-sectional view illustrating a display panel illustrated in FIG. 4;

FIG. 6 is a schematic plan view of the display panel illustrated in FIG. 5;

FIG. 7 is a schematic perspective view of a bonding device according to an embodiment;

FIG. 8 is a schematic side view of a bonding device according to an embodiment when viewed in a second direction;

FIG. 9 is a schematic front view of a bonding device according to an embodiment when viewed in a first direction;

FIGS. 10A and 10B are enlarged schematic views of a first movable rod and a bracket according to an embodiment;

FIGS. 11A and 11B are enlarged schematic views of a first movable rod and a back pressure bracket; and

FIGS. 12A, 12B, 12C, 12D, 12E, 12F, and 12G are schematic front views of a bonding device according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art. For example, “about” may mean within one or more standard deviations, or within ±20%, ±10%, or ±5% of the stated value.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, embodiments will be described with reference to the drawings.

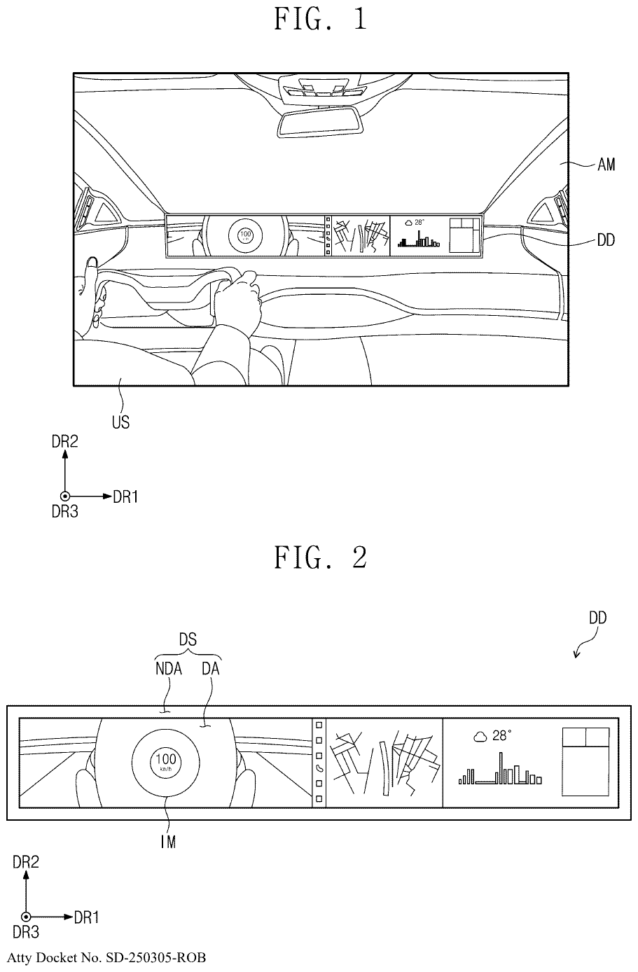

FIG. 1 is a schematic view illustrating an automobile interior in which a display device implemented by a bonding device according to an embodiment is disposed. FIG. 2 is a schematic plan view of the display device illustrated in FIG. 1.

Referring to FIG. 1, a display device DD may be disposed inside an automobile AM. The display device DD may be disposed inside the automobile AM and provide various information to a driver US (hereinafter, referred to as a user). The display device DD may provide information such as speed, weather, or maps to the user US. The display device DD may be defined as a touch display which operates according to a touch input of the user US.

Referring to FIGS. 1 and 2, the display device DD according to an embodiment may have a quadrilateral shape which has long sides extending in a first direction DR1 and short sides extending in a second direction DR2 intersecting the first direction DR1. However, an embodiment is not limited thereto, and the display device DD may have various shapes, such as a circular or polygonal shape.

Hereinafter, a direction, which is substantially perpendicular to a plane defined by the first direction DR1 and the second direction DR2, is defined as a third direction DR3. Also, in this description, the wording, “when viewed on a plane” or “in a plan view” may mean a state when viewed in the third direction DR3.

An upper surface of the display device DD which provides images to the user US may be defined as a display surface DS and have a plane defined by the first direction DR1 and the second direction DR2. Images IM generated by the display device DD through the display surface DS may be provided to the user US. The display device DD may sense a touch of the user US.

The display surface DS may include a display region DA and a non-display region NDA around the display region DA. The display region DA may display images, and the non-display region NDA may not display images. The non-display region NDA may surround the display region DA and define a border of the display device DD printed in a predetermined or certain color.

An automobile display device DD is illustrated as an example, but an embodiment is not limited thereto. For example, the display device DD according to an embodiment may also be used for an electronic apparatus such as a smartphone, a digital camera, a laptop computer, a monitor, and a smart television which provide images to a user.

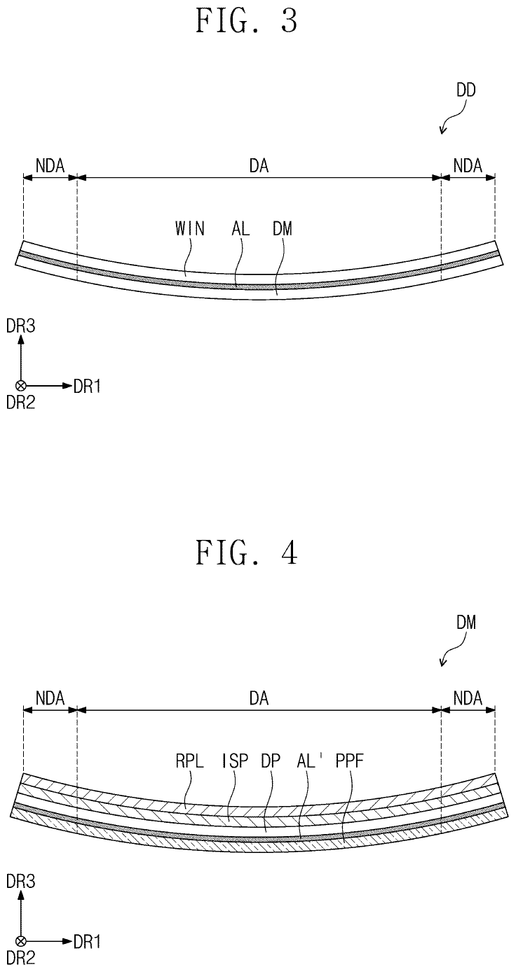

FIG. 3 is a schematic cross-sectional view of a display module and a window of a display device.

For example, FIG. 3 illustrates a cross-section of a display module DM and a window WIN when viewed in the second direction DR2.

Referring to FIG. 3, a display device DD may include the display module DM, and the window WIN disposed on the display module DM. The window WIN may protect the display module DM from external scratches or impacts.

The window WIN and the display module DM may have curved surfaces. The window WIN and the display module DM may be curved or bent downward in a concave manner. An adhesive layer AL may be disposed between the display module DM and the window WIN. The adhesive layer AL may bond the display module DM and the window WIN. The adhesive layer AL may include a pressure sensitive adhesive (PSA) or an optically clear adhesive (OCA), but a type of adhesive is not limited thereto.

FIG. 4 is a schematic cross-sectional view illustrating the display module illustrated in FIG. 3.

For example, FIG. 4 illustrates a cross-section of a display module DM when viewed in the second direction DR2.

Referring to FIG. 4, the display module DM may include a display panel DP, an input-sensing unit ISP, an anti-reflection layer RPL, a panel protection film PPF, and an adhesive layer AL′.

The display panel DP according to an embodiment may be a light-emitting display panel. For example, the display panel DP may be an organic light-emitting display panel or an inorganic light-emitting display panel. A light-emitting layer of the organic light-emitting display panel may include an organic light-emitting material. A light-emitting layer of the inorganic light-emitting display panel may include quantum dots, quantum rods, etc. Hereinafter, the display panel DP is described as an organic light-emitting display panel.

The input-sensing unit ISP may be disposed on the display panel DP. The input-sensing unit ISP may include sensor units for sensing an external input in a capacitive manner. The input-sensing unit ISP may be directly manufactured on the display panel DP in case that the display device DD is manufactured. However, an embodiment is not limited thereto. The input-sensing unit ISP may be manufactured as a panel separately from the display panel DP and then attached to the display panel DP via an adhesive layer.

The anti-reflection layer RPL may be disposed on the input-sensing unit ISP. The anti-reflection layer RPL may be directly manufactured on the input-sensing unit ISP in case that the display device DD is manufactured. However, an embodiment is not limited thereto. The anti-reflection layer RPL may be separately manufactured as a panel and then attached to the input-sensing unit ISP via an adhesive layer.

The anti-reflection layer RPL may be defined as an external light anti-reflection film. The anti-reflection layer RPL may reduce reflectance for external light which enters the display panel DP from above the display device DD. Due to the anti-reflection layer RPL, the external light may be invisible to a user.

In case that external light propagating toward the display panel DP is reflected at the display panel DP and is re-provided to an external user, the external light may be visible to a user as if reflected from a mirror. In order to prevent this phenomenon, the anti-reflection layer RPL may include, for example, color filters which display the same colors as pixels of the display panel DP.

The color filters may filter external light with colors corresponding to the colors of pixels. For example, the external light may be invisible to a user. However, an embodiment is not limited thereto, and the anti-reflection layer RPL may include a retarder and/or a polarizer for reducing the reflectance for external light.

The panel protection film PPF may be disposed below the display panel DP. The panel protection film PPF may protect a lower part of the display panel DP. The panel protection film PPF may include a flexible plastic material such as polyethyleneterephthalate (PET).

The adhesive layer AL′ may be disposed between the display panel DP and the panel protection film PPF. The adhesive layer AL′ may bond the display panel DP and the panel protection film PPF. The adhesive layer AL′ may include a pressure sensitive adhesive or an optically clear adhesive, but a type of adhesive is not limited thereto.

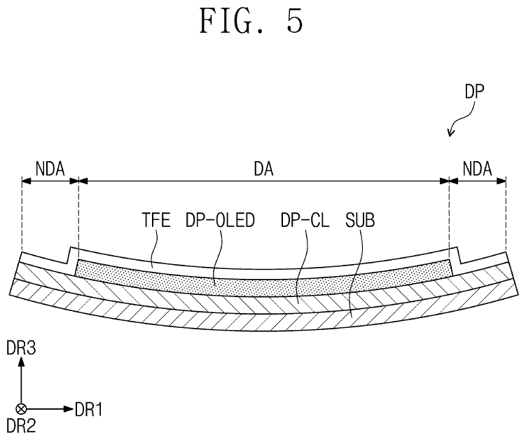

FIG. 5 is a schematic cross-sectional view illustrating the display panel illustrated in FIG. 4.

For example, FIG. 5 illustrates a cross-section of a display panel DP when viewed in the second direction DR2.

Referring to FIG. 5, the display panel DP may include a substrate SUB, a circuit element layer DP-CL disposed on the substrate SUB, a display element layer DP-OLED disposed on the circuit element layer DP-CL, and a thin-film encapsulation layer TFE disposed on the display element layer DP-OLED.

The substrate SUB may include a display region DA and a non-display region NDA around the display region DA. The substrate SUB may include glass or a flexible plastic material such as polyimide (PI).

The display element layer DP-OLED may be disposed in the display region DA. The display element layer DP-OLED may generate an image.

Pixels may be disposed on the circuit element layer DP-CL and the display element layer DP-OLED. The pixels may each include a transistor disposed on the circuit element layer DP-CL, and a light-emitting element which is disposed on the display element layer DP-OLED and is connected to the transistor.

The thin-film encapsulation layer TFE may be disposed on the circuit element layer DP-CL so as to cover the display element layer DP-OLED. The thin-film encapsulation layer TFE may protect the pixels from moisture, oxygen, and external foreign substances.

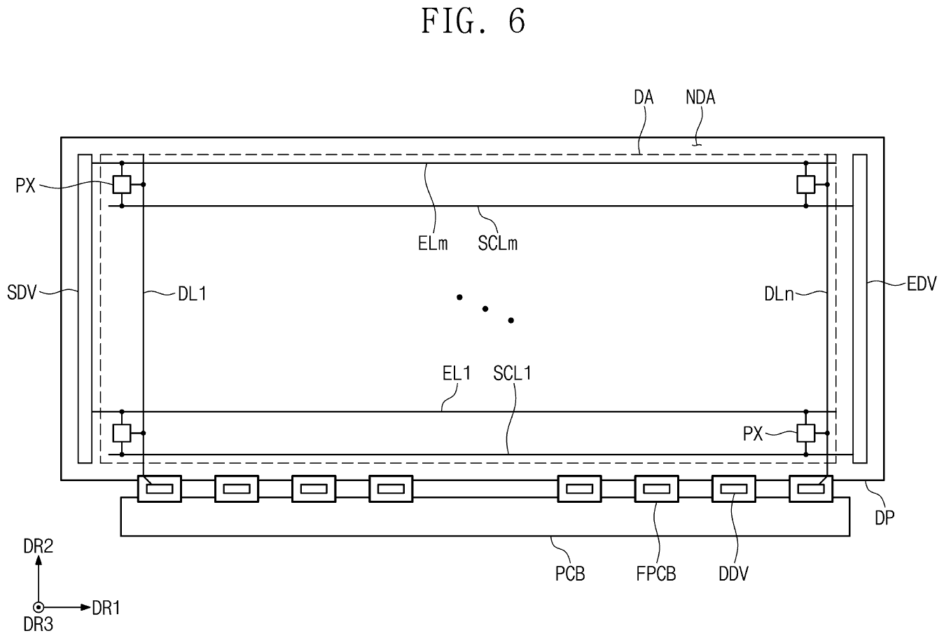

FIG. 6 is a schematic plan view of the display panel illustrated in FIG. 5.

Referring to FIG. 6, a display device DD may include a display panel DP, a scan driver SDV, data drivers DDV, flexible circuit boards FPCB, an emission driver EDV, and a printed circuit board PCB.

The display panel DP may include a display region DA and a non-display region NDA around the display region DA. The display region DA and the non-display region NDA of the display panel DP may respectively correspond to the display region DA and the non-display region NDA illustrated in FIG. 5. The display panel DP may have a rectangular shape which has long sides extending in the first direction DR1 and short sides extending in the second direction DR2, but a shape of the display panel DP is not limited thereto.

The display panel DP may include pixels PX, scan lines SCL1 to SCLm, data lines DL1 to DLn, and emission lines EL1 to ELm. m and n may be natural numbers.

The pixels PX may be disposed in the display region DA. The scan driver SDV and the emission driver EDV may be disposed in the non-display region NDA adjacent to the respective short sides of the display panel DP.

The data drivers DDV may be disposed adjacent to a lower side of the display panel DP which is defined as one of the long sides of the display panel DP in a plan view. The printed circuit board PCB may be disposed adjacent to the lower side of the display panel DP in a plan view. The flexible circuit boards FPCB may be connected to the lower side of the display panel DP and the printed circuit board PCB. The data drivers DDV may be manufactured in the form of an integrated circuit chip and be mounted on the respective flexible circuit boards FPCB.

The scan lines SCL1 to SCLm may extend in the first direction DR1 to be connected to the pixels PX and the scan driver SDV. The emission lines EL1 to ELm may extend in the first direction DR1 to be connected to the pixels PX and the emission driver EDV.

The data lines DL1 to DLn may extend in the second direction DR2 to be connected to the pixels PX and the data drivers DDV. For example, the two data lines DL1 and DLn connected to the data drivers DDV, which are arranged respectively on the leftmost side and the rightmost side, are illustrated, but substantially, the data lines may be connected to the respective data drivers DDV.

For example, the display device DD may further include a timing controller that controls the operations of the scan driver SDV, the data drivers DDV, and the emission driver EDV. The timing controller may be manufactured in the form of an integrated circuit chip and be mounted on the printed circuit board PCB. The timing controller may be connected to the data drivers DDV, the scan driver SDV, and the emission driver EDV via the printed circuit board PCB and the flexible circuit board FPCB.

The scan driver SDV may generate scan signals, and the scan signals may be applied to the pixels PX via the scan lines SCL1 to SCLm. The data drivers DDV may generate data voltages, and the data voltages may be applied to the pixels PX via the data lines DL1 to DLn. The emission driver EDV may generate emission signals, and the emission signals may be applied to the pixels PX via the emission lines EL1 to ELm.

The pixels PX may receive data voltages in response to the scan signals. The pixels PX may display images by emitting light having luminances corresponding to the data voltages in response to the emission signals. Emission times of the pixels PX may be controlled by the emission signals.

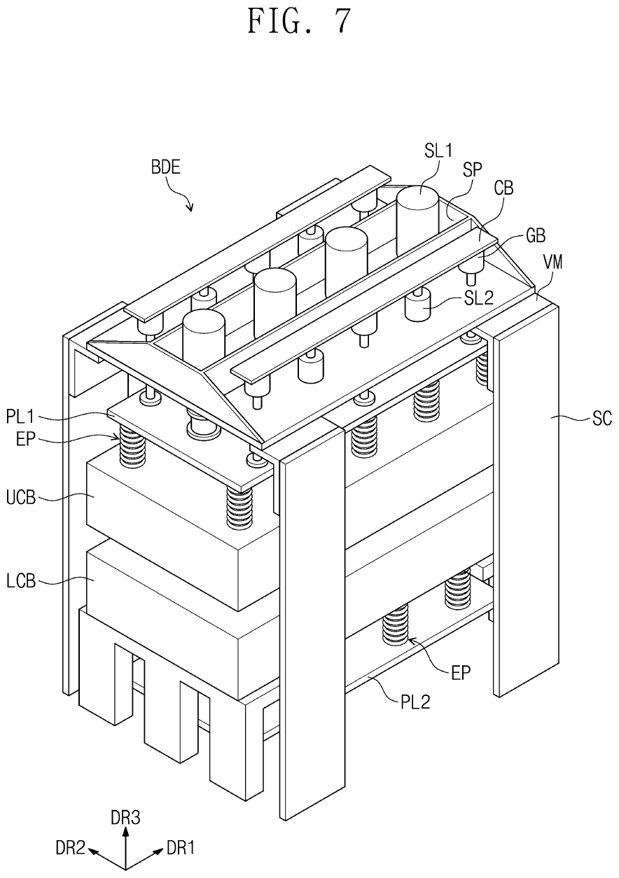

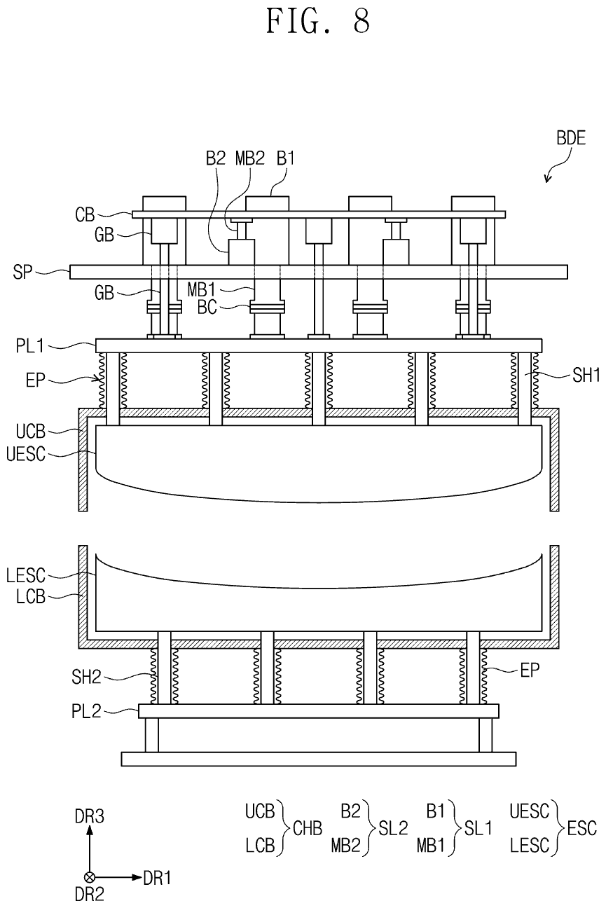

FIG. 7 is a schematic perspective view of a bonding device according to an embodiment. FIG. 8 is a schematic side view of a bonding device according to an embodiment when viewed in the second direction.

For convenience of description, internal structures of an upper chamber UCB and a lower chamber LCB are omitted in FIG. 7. For convenience of description, a support pillar SC and a vertical moving part VM are omitted in FIG. 8.

Referring to FIGS. 7 and 8, a bonding device BDE may include an electrostatic chuck ESC, a chamber CHB, first shafts SH1, second shafts SH2, a first plate PL1, a second plate PL2, elastic parts EP, a bracket BC, a support plate SP, first cylinders SL1, guide rods GB, second cylinders SL2, and connection bars CB.

The electrostatic chuck ESC may include electrodes. The electrodes may be alternately disposed in a direction. The electrodes may be applied with voltages having different polarities. The electrodes having different polarities may generate electrostatic forces. Process objects may be fixed to the electrostatic chuck ESC due to the electrostatic force generated from the electrostatic chuck ESC. For example, vacuum suction holes for fixing the process object may be defined in the electrostatic chuck ESC.

The electrostatic chuck ESC may include an upper electrostatic chuck UESC and a lower electrostatic chuck LESC. The upper electrostatic chuck UESC may be disposed above the lower electrostatic chuck LESC. A lower surface of the upper electrostatic chuck UESC may have a convex curved surface. The lower electrostatic chuck LESC may be disposed below the upper electrostatic chuck UESC (for example, a direction opposite to the third direction DR3). An upper surface of the lower electrostatic chuck LESC may have a concave curved surface. The upper surface of the lower electrostatic chuck LESC and the lower surface of the upper electrostatic chuck UESC may have shapes corresponding to each other. The upper surface of the lower electrostatic chuck LESC and the lower surface of the upper electrostatic chuck UESC are illustrated as having curved surfaces, but may have various shapes according to shapes of process objects.

The chamber CHB may include an upper chamber UCB and a lower chamber LCB disposed below the upper chamber UCB. The upper electrostatic chuck UESC may be disposed inside the upper chamber UCB. The lower electrostatic chuck LESC may be disposed inside the lower chamber LCB. The upper chamber UCB may move in a downward direction (e.g., the direction opposite to the third direction DR3) and be in contact with (e.g., in direct contact with) the lower chamber LCB. In case that the upper chamber UCB and the lower chamber LCB are in contact with (e.g., in direct contact with) each other, the chamber CHB in a vacuum state may be formed. The details thereof will be described later.

The first shafts SH1 may be disposed on the upper electrostatic chuck UESC. The first shafts SH1 may be disposed in spaces defined inside the elastic parts EP. For example, the diameter of each of the elastic parts EP may be greater than the diameter of each of the first shafts SH1. The first shafts SH1 may penetrate the upper chamber UCB to be connected to the upper electrostatic chuck UESC. The first shafts SH1 may be arranged to be spaced apart from each other along the first direction DR1.

The second shafts SH2 may be disposed under the lower electrostatic chuck LESC (for example, the direction opposite to the third direction DR3). The second shafts SH2 may be disposed in spaces defined inside the elastic parts EP. For example, the diameter of each of the elastic parts EP may be greater than the diameter of each of the second shafts SH2. The second shafts SH2 may penetrate the lower chamber LCB to be connected to the lower electrostatic chuck LESC. The second shafts SH2 may be arranged to be spaced apart from each other along the first direction DR1.

The first plate PL1 may be disposed on the first shafts SH1 and the elastic parts EP. The second plate PL2 may be disposed under the second shafts SH2 and the elastic parts EP.

The elastic parts EP may be disposed on the upper chamber UCB. The elastic parts EP may be disposed above the upper electrostatic chuck UESC. The elastic parts EP may be disposed under the lower chamber LCB. Spaces may be defined inside the elastic parts EP. The elastic part EP may provide an elastic force to the first plate PL1 and the upper chamber UCB in a vertical direction (for example, the third direction DR3 and the direction opposite to the third direction DR3). In case that the upper electrostatic chuck UESC moves in the direction opposite to the third direction DR3, the elastic parts EP may protect the chamber CHB and help the upper electrostatic chuck UESC move in the direction opposite to the third direction DR3. The details thereof will be described later.

The brackets BC may be disposed on the first plate PL1. The brackets BC may be fixed to the first plate PL1, and lengths of the brackets BC may not vary. The brackets BC may be disposed so as to correspond to the first cylinders SL1. For example, the brackets BC may be disposed so as to respectively overlap the first cylinders SL1. The brackets BC may be arranged to be spaced apart from each other along the first direction DR1. The brackets BC may be arranged in the first direction DR1 at the center of the first plate PL1 with respect to the second direction DR2.

The support plate SP may be disposed above the first plate PL1. For convenience of description, FIG. 8 schematically illustrates the support plate SP.

The first cylinders SL1 may be disposed on the brackets BC. The first cylinders SL1 may be disposed on the support plate SP and extend towards the brackets BC. The first cylinders SL1 may be arranged to be spaced apart from each other along the first direction DR1.

The first cylinders SL1 may each be connected to the upper electrostatic chuck UESC via the brackets BC, the first plate PL1, and the first shafts SH1. The first cylinders SL1 may provide a thrust force. A thrust force provided by the first cylinders SL1 may be transmitted to the upper electrostatic chuck UESC, and the first cylinders SL1 may uniformly transmit the thrust force to the upper electrostatic chuck UESC.

The first cylinders SL1 may each include a first body B1 and a first movable rod MB1. The first body B1 may be disposed on the support plate SP. The first body B1 may have a piston-shaped interior structure.

The first movable rod MB1 may penetrate the support plate SP and extend below the support plate SP. The first movable rod MB1 may vertically move (for example, the third direction DR3 and the direction opposite to third direction DR3). For example, the first movable rod MB1 may move toward the inside of the first body B1 in case of moving in the third direction DR3. For example, as a piston inside the first body B1 moves in the third direction DR3, the first movable rod MB1 may move in the third direction DR3.

The first movable rod MB1 may extend from the first body B1 to a direction toward the bracket BC (e.g., the direction opposite to the third direction DR3) and be disposed on the bracket BC. The first movable rod MB1 may be in contact with (e.g., in direct contact with) an upper surface of the bracket BC. In case that the first movable rod MB1 moves in the direction opposite to the third direction DR3, a thrust force may be transmitted to the bracket BC.

The guide rod GB may be disposed on the first plate PL1. The guide rod GB may extend above the support plate SP through a hole defined in the support plate SP. For example, the guide rod GB may extend from the first plate PL1 toward the support plate SP and penetrate the support plate SP.

The guide rods GB may each be spaced apart from the first cylinders SL1 in the second direction DR2. The guide rods GB may be arranged to be spaced apart from each other in the first direction DR1.

The guide rods GB may move in the third direction DR3 and the direction opposite to the third direction DR3. For example, the guide rods GB may move vertically (for example, the third direction DR3 and the direction opposite to the third direction DR3). The guide rods GB may be connected to the first plate PL1.

Due to the guide rods GB, a position of the support plate SP may be fixed without being displaced in the first direction DR1 and the second direction DR2.

The second cylinders SL2 may be disposed on the support plate SP. The second cylinders SL2 may be disposed adjacent to the guide rod GB in the horizontal direction (for example, the first direction DR1). The second cylinders SL2 may be spaced apart from the first cylinders SL1 in the second direction DR2. The second cylinders SL2 may be arranged to be spaced apart from each other in the first direction DR1. Some of the second cylinders SL2 may be disposed between the guide rods GB in the first direction DR1. For example, the guide rods GB and the second cylinders SL2 may be alternately arranged in the first direction DR1.

The second cylinders SL2 may each include a second body B2 and a second movable rod MB2. The second body B2 may be disposed on the support plate SP. The second body B2 may have a piston-shaped interior structure.

The second movable rod MB2 may be connected to an upper part of the second body B2. The second movable rod MB2 may extend to the upper part of the second body B2. The second movable rod MB2 may vertically move (for example, the third direction DR3 and the direction opposite to the third direction DR3). For example, the second movable rod MB2 may move toward the inside of the second body B2 in case of moving in the direction opposite to the third direction DR3. For example, as a piston inside the second body B2 moves in the direction opposite to the third direction DR3, the second movable rod MB2 may move in the direction opposite to the third direction DR3.

The connection bar CB may connect the guide rods GB and the second cylinders SL2. The connection bar CB may be disposed on the guide rods GB and the second cylinders SL2. For example, the connection bar CB may be connected to an upper end portion of each of the guide rods GB and an upper end portion of the second movable rod MB2 of each of the second cylinders SL2. The second movable rods MB2 may each be connected to the upper end portions of the guide rods GB via the connection bar CB. The second cylinders SL2 may be connected to the upper end portions of the guide rods GB. Due to the connection bar CB, the guide rods GB and the second cylinders SL2 may move in the third direction DR3 by the same distance.

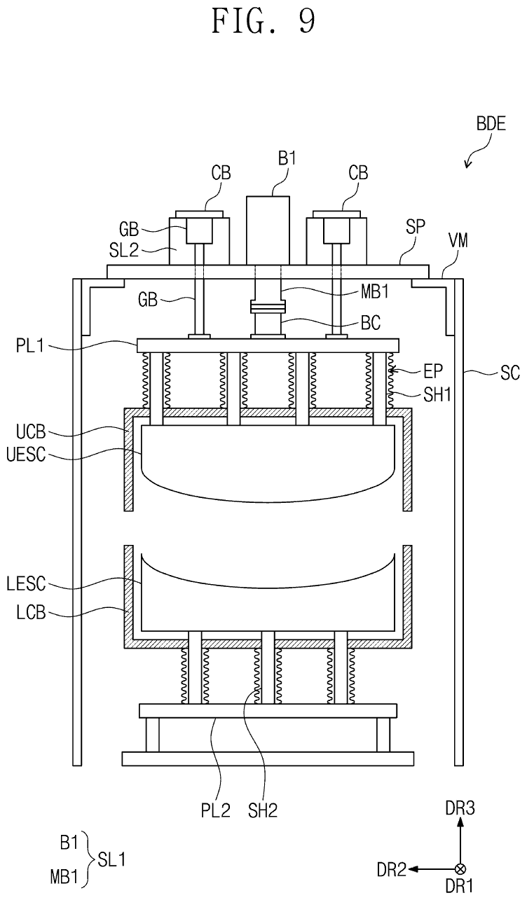

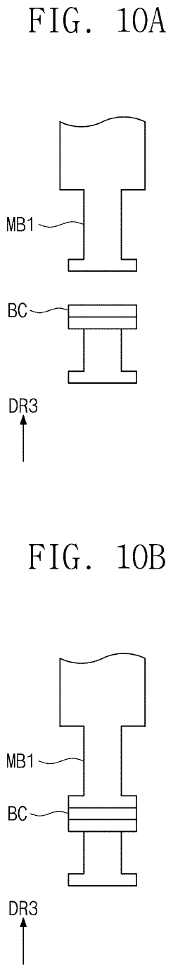

FIG. 9 is a schematic front view of a bonding device according to an embodiment when viewed in the first direction DR1.

Referring to FIGS. 7 and 9, the bonding device BDE may further include the support pillar SC and the vertical moving part VM.

The support pillar SC may be adjacent to a side of the support plate SP. The support pillar SC may be provided in plurality. The support pillars SC may be arranged to be spaced apart from each other in the first direction DR1 and be located to be spaced apart from each other in the second direction DR2. The support pillars SC may be symmetrically disposed to each other at a virtual center line, in the second direction DR2, of a long side of the support plate SP extending in the first direction DR1 and at a virtual center line, in the first direction DR1, of a short side extending in the second direction DR2. The support pillars SC may form a resistance moment to the moment generated in case that components disposed on the first plate PL1 and components connected to the first plate PL1 move in the third direction DR3.

The vertical moving part VM may be connected to a side of the support plate SP and the support pillar SC. The support plate SP may be disposed on the vertical moving part VM. The vertical moving part VM may move in a vertical direction (for example, a direction parallel to the third direction DR3). The support plate SP and the first plate PL1 may move in a downward direction while (or in case that) the first cylinder SL1 generates a thrust force in the direction opposite to the third direction DR3 (or the downward direction). For example, the support plate SP and the vertical moving part VM connected to the support plate SP may move together in the downward direction. The vertical moving part VM may be provided in plurality. The vertical moving parts VM may be respectively connected to the support pillars SC.

FIGS. 10A and 10B are enlarged schematic views of a first movable rod and a bracket according to an embodiment.

FIG. 10A is a schematic view illustrating a state in which a first movable rod MB1 and a bracket BC are separated. FIG. 10B is a schematic view illustrating a state in which the first movable rod MB1 and the bracket BC are in contact with (e.g., in direct contact with) each other.

Referring to FIGS. 10A and 10B, the first movable rod MB1 may be disposed on the bracket BC and be separated from the bracket BC. The first movable rod MB1 may be separated from the bracket BC in case that the first movable rod MB1 performs piston motion inside the first body B1 (see FIG. 9).

During a bonding process of the window and the display module, the first movable rod MB1 may be in contact with (e.g., in direct contact with) an upper surface of the bracket BC. In case that the first movable rod MB1 performs piston motion and moves toward the direction opposite to the third direction DR3, the first movable rod MB1 may be in contact with (e.g., in direct contact with) the upper surface of the bracket BC. Therefore, in case that the first cylinder SL1 (see FIG. 9) generates a thrust force in the direction opposite to the third direction DR3, the first movable rod MB1 is in contact with (e.g., in direct contact with) the bracket BC, and thus the thrust force of the first cylinder SL1 may be transmitted to the bracket BC.

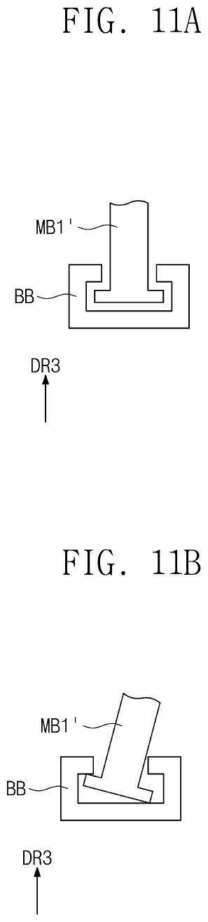

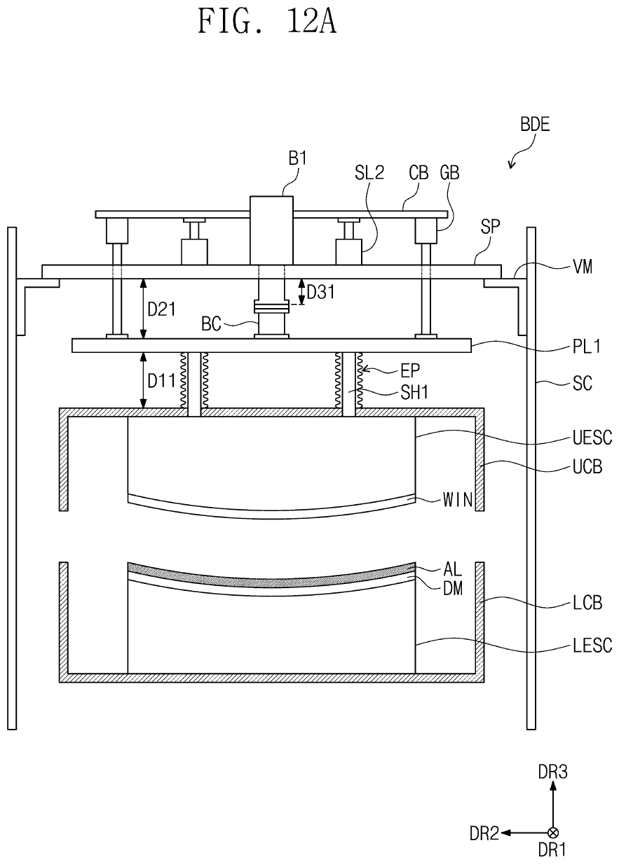

FIGS. 11A and 11B are enlarged schematic views of a first movable rod and a back pressure bracket.

Referring to FIGS. 11A and 11B, FIGS. 11A and 11B are illustrated as examples of using a back pressure bracket BB instead of the bracket BC (see FIG. 10A) according to an embodiment. In case that a first movable rod MB1′ moves in the third direction DR3, an end portion of the back pressure bracket BB is in contact with (e.g., in direct contact with) the first movable rod MB1′, and thus a back pressure may be applied. Due to a tolerance between the back pressure bracket BB and the first movable rod MB1′, the first movable rod MB1′ and the back pressure bracket BB may be in asymmetrical contact with each other. For example, the back pressure may not be applied to a bonding device BDE.

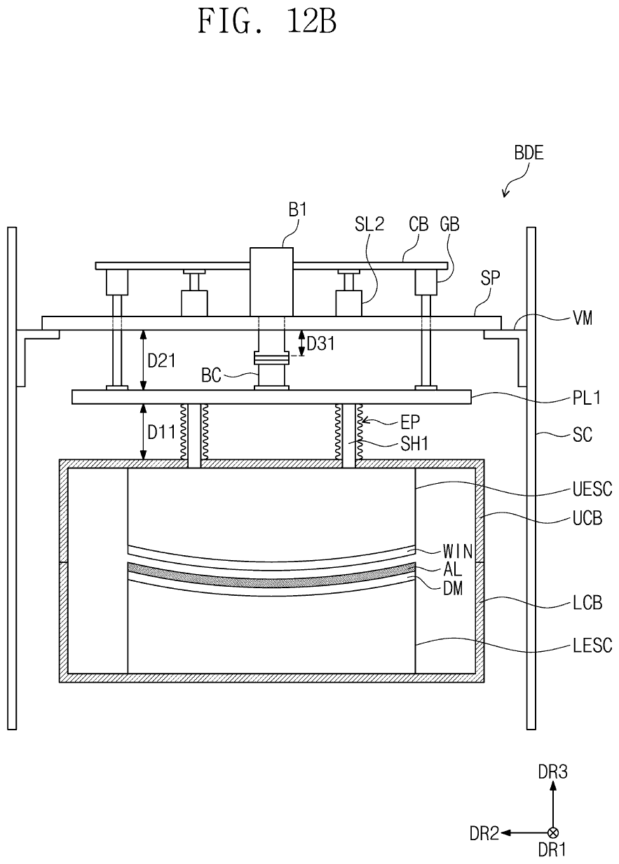

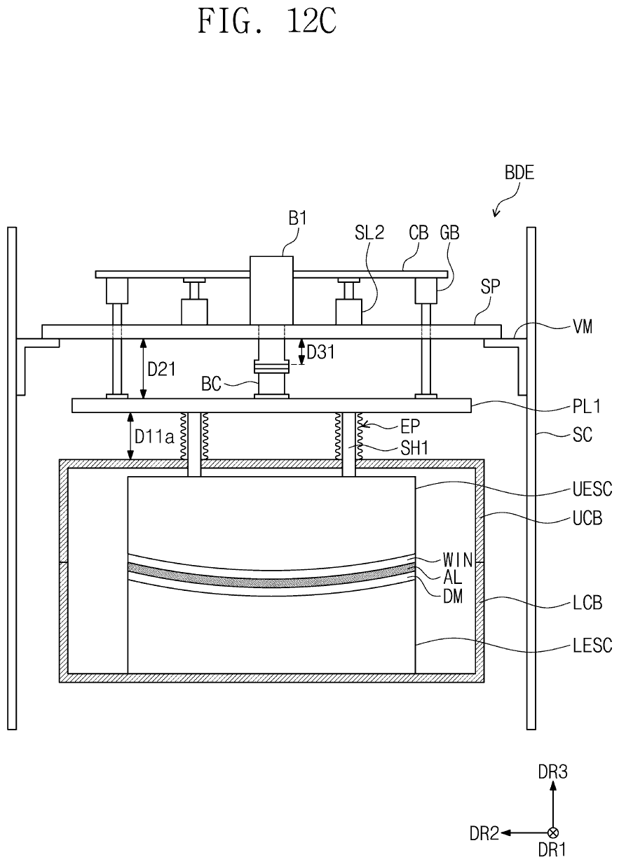

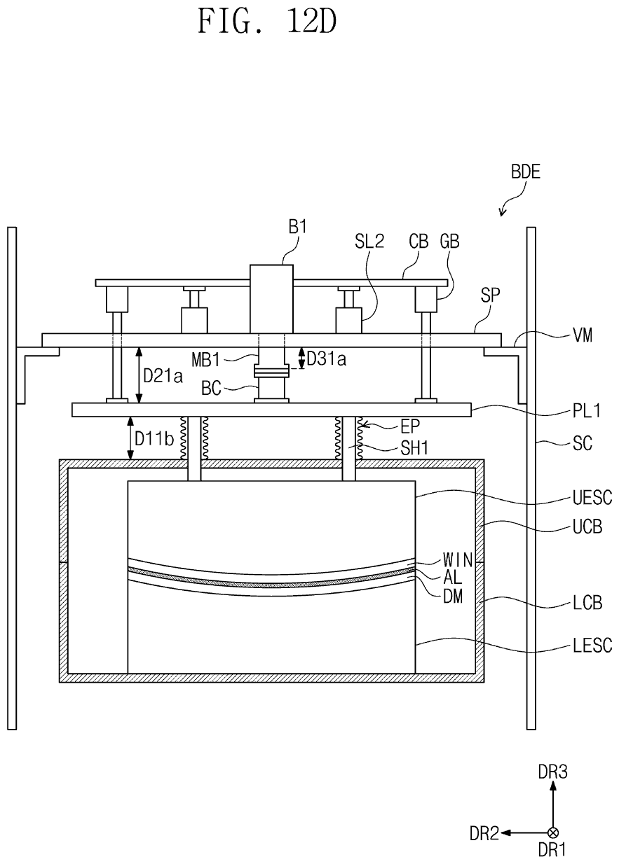

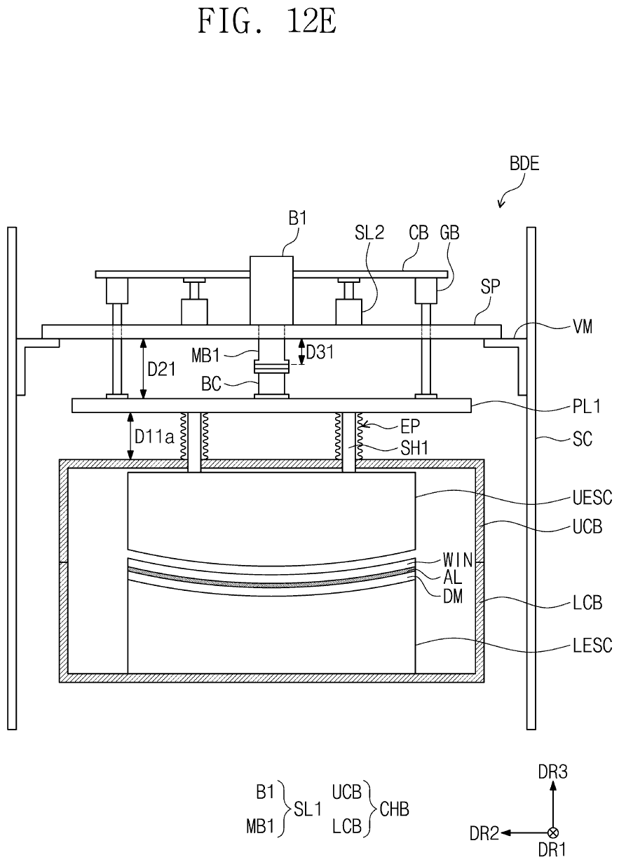

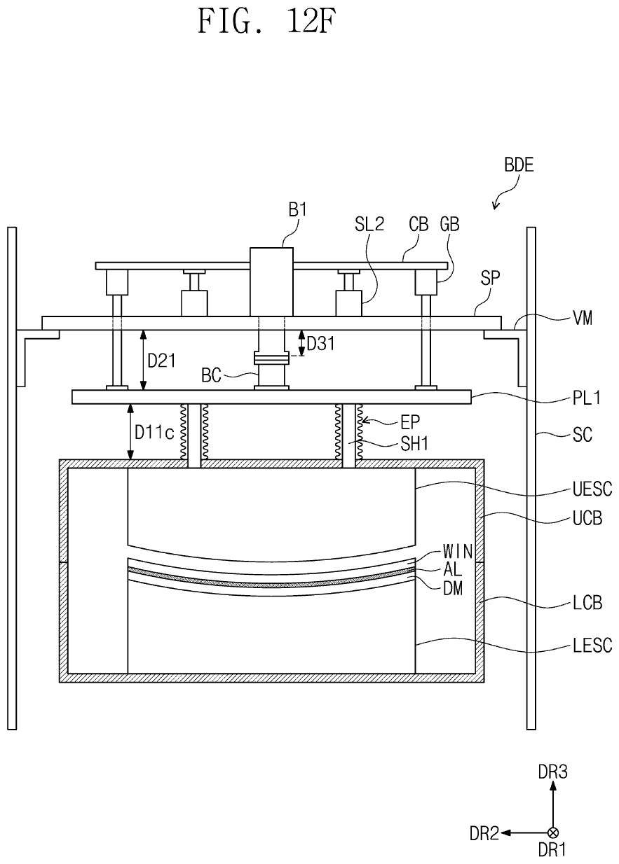

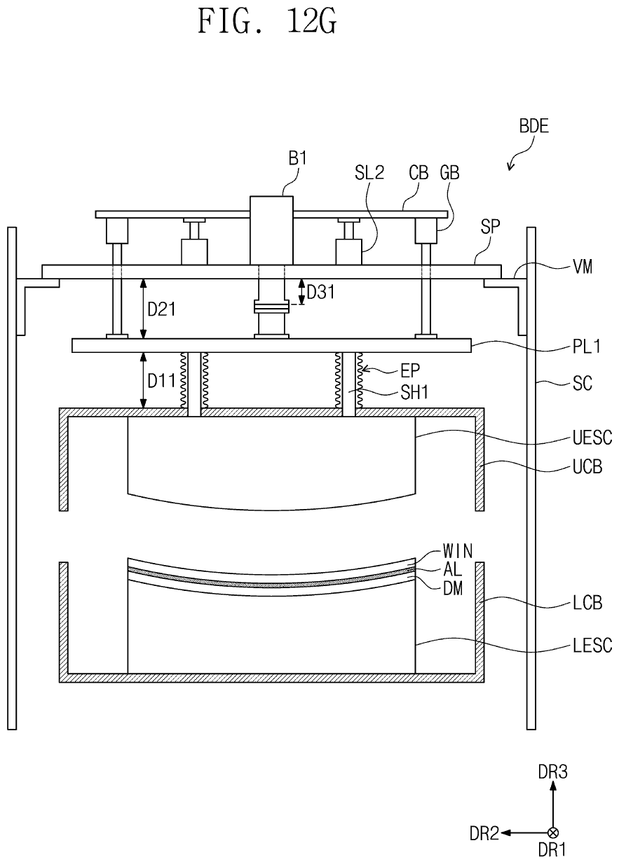

FIGS. 12A to 12G are schematic front views of a bonding device according to an embodiment. For operation description, FIGS. 12A to 12G illustrate configurations different from an actual configuration. FIGS. 12A to 12G illustrate two second cylinders SL2, two guide rods GB, and two elastic parts EP.

FIG. 12A is a schematic view illustrating a standby state before a bonding process is performed.

Referring to FIG. 12A, a display module DM may be disposed on an upper surface of a lower electrostatic chuck LESC. An adhesive layer AL may be disposed on an upper surface of the display module DM. A window WIN may be disposed on a lower surface of an upper electrostatic chuck UESC. A distance between a first plate PL1 and an upper chamber UCB may be a (1-1)-th distance D11. A distance between the first plate PL1 and a support plate SP may be a (2-1)-th distance D21. A distance between an upper surface of a bracket BC and the support plate SP may be a (3-1)-th distance D31.

FIG. 12B is a schematic view illustrating a state for which a vacuum is formed inside a chamber during the bonding process.

Referring to FIG. 12B, a vertical moving part VM may move in the direction opposite to the third direction DR3 (for example, the downward direction). The vertical moving part VM may move in the downward direction and the upper chamber UCB may be in contact with (e.g., in direct contact with) a lower chamber LCB. For example, the (1-1)-th distance D11, the (2-1)-th distance D21, and the (3-1)-th distance D31 may be the same as those of FIG. 12A, and the vertical moving part VM may move by a distance between the upper chamber UCB and the lower chamber LCB. In case that the upper chamber UCB is in contact with (e.g., in direct contact with) the lower chamber LCB, a vacuum may be formed inside the chamber. Under the vacuum state, it may be facilitated to bond the window WIN and the display module DM in case that the window WIN and the display module DM are bonded via the adhesive layer AL.

FIG. 12C is a schematic view illustrating a state in which the window WIN is in contact with (e.g., in direct contact with) the adhesive layer AL during the bonding process.

Referring to FIG. 12C, the vertical moving part VM may move in the downward direction. A distance by which the vertical moving part VM moves in the downward direction may be the same as a distance between the window WIN and the adhesive layer AL of FIG. 12B. The distance between the window WIN and the adhesive layer AL of FIG. 12B may be a first distance. The first distance may be a scalar. A (1-1)-th distance D11a may be shorter than the (1-1)-th distance D11 of FIG. 12B. A difference between the (1-1)-th distance D11 of FIG. 12B and the (1-1)-th distance D11a may mean the first distance. The elastic part EP may be retracted by the first distance. A distance between a lower surface of the upper chamber UCB and the upper electrostatic chuck UESC may be extended by the first distance. For example, since a length of the first shaft SH1 is constant, the vertical moving part VM may move in the downward direction by the first distance, the upper electrostatic chuck UESC may be spaced apart from the lower surface of the upper chamber UCB by the first distance, the (2-1)-th distance D21 and the (3-1)-th distance D31 may be the same as those of FIG. 12B, and thus the window WIN may be in contact with (e.g., in direct contact with) the adhesive layer AL.

FIG. 12D is a schematic view illustrating a state in which the window WIN and the display module DM are bonded via the adhesive layer AL during the bonding process.

Referring to FIG. 12D, the vertical moving part VM may move in a downward direction. As the vertical moving part VM moves in the downward direction, the window WIN, which is a process object disposed on the lower surface of the upper electrostatic chuck UESC, may be bonded to the adhesive layer AL and the display module DM which are process objects disposed on the upper surface of the lower electrostatic chuck LESC. For example, the vertical moving part VM may move in the downward direction (for example, the direction opposite to the third direction DR3 or a downward direction) by the first distance.

A first movable rod MB1 may move towards a first body B1 by a second distance shorter than the first distance. The second distance may be half the first distance. The first movable rod MB1 may perform piston motion and move inside the first body B1 by the second distance, and thus a (3-1)-th distance D31a may be shorter than the (3-1)-th distance D31 of FIG. 12C by the second distance.

The guide rod GB may perform piston motion inside the cylinder of an upper part of the guide rod GB and move in the third direction DR3 by the second distance. Therefore, a (2-1)-th distance D21a may be shorter than the (2-1)-th distance D21 of FIG. 12C by the second distance.

Even when the first movable rod MB1 and the guide rod GB perform piston motion and move in the third direction DR3 by the second distance and the vertical moving part VM moves in a downward direction by the first distance, the first plate PL1 may move by the second distance. Therefore, a (1-1)-th distance D11b may be shorter than the (1-1)-th distance D11a of FIG. 12C by the second distance. The elastic part EP may be retracted by the second distance. A distance between a lower surface of the upper chamber UCB and the upper electrostatic chuck UESC may be further extended by the second distance. The distance between the lower surface of the upper chamber UCB and the upper electrostatic chuck UESC may be obtained by summing (or adding) the first distance and the second distance, compared to the distance between the lower surface of the upper chamber UCB and the upper electrostatic chuck UESC illustrated in FIG. 12B. For example, since a length of the first shaft SH1 is constant, the vertical moving part VM moves by the first distance, a distance between the upper electrostatic chuck UESC and the lower surface of the upper chamber UCB may be further extended by the second distance, and thus the adhesive layer AL may bond the window WIN and the display module DM. The adhesive layer AL may have a thickness decreased by the second distance, thereby bonding the window WIN and the display module DM.

FIG. 12E is a schematic view illustrating a state in which the vacuum state is released after bonding process and the upper electrostatic chuck is separated.

Referring to FIG. 12E, the second cylinder SL2 may apply, in the third direction DR3, a force equal to the total weight of the first cylinder SL1, the support plate SP, the first plate PL1, the first shaft SH1, the elastic part EP, and the upper electrostatic chuck UESC. The vertical moving part VM may be moved by the second cylinder SL2 in the third direction DR3. The vertical moving part VM may move in the third direction DR3 by the first distance. The vacuum inside the chamber CHB may be released before the vertical moving part VM moves.

The elastic part EP may be stretched in the third direction DR3 by the second distance. The (1-1)-th distance D11a may mean a length which becomes longer than the (1-1)-th distance D11b of FIG. 12D by the second distance, and mean a length which becomes shorter than the (1-1)-th distance D11 of FIG. 12B by a first length. Since the length of the first shaft SH1 is constant, the distance between the upper chamber UCB and the upper electrostatic chuck UESC may be the second distance.

The first movable rod MB1 may perform piston motion inside the first body B1 of the first cylinder SL1. The first movable rod MB1 may be repositioned by the second distance in the direction opposite to the third direction DR3 inside the first body B1 while (or in case that) the vertical moving part VM moves in the third direction DR3. Accordingly, the (3-1)-th distance D31 may become longer than the (3-1)-th distance D31a of FIG. 12D by the second distance.

The guide rod GB may perform the piston motion inside the cylinder of the upper part of the guide rod GB and move in the direction opposite to the third direction DR3 by the second distance. Therefore, the (2-1)-th distance D21 may become longer than the (2-1)-th distance D21a of FIG. 12D by the second distance.

FIGS. 12F and 12G are schematic views illustrating a state in which the chamber is separated after the bonding process.

Referring to FIG. 12F, the vertical moving part VM may move in the third direction DR3. The vertical moving part may move in the third direction DR3 by the first distance. The elastic part EP may be stretched in the third direction DR3 by the second distance. The vertical moving part VM may move by the first distance, and the elastic part EP may be stretched by the second distance. Accordingly, the upper electrostatic chuck UESC may move in the third direction DR3 by the second distance. A (1-1)-th distance D11c may become shorter than the (1-1)-th distance D11a of FIG. 12E by the second distance, and become shorter than the (1-1)-th distance D11 of FIG. 12B by the second distance.

Referring to FIG. 12G, as the second cylinder SL2 applies a back pressure in the third direction DR3, the vertical moving part VM may move in the third direction DR3, and thus the upper chamber UCB and the lower chamber LCB may be separated. The upper chamber UCB and the lower chamber LCB may be separated, and finally, the bonding of the window WIN and the display module DM may be completed.

According to an embodiment, a first cylinder may apply a thrust force, and a second cylinder may apply a back pressure. A bonding failure of a display module and a window may be prevented by separating a thrust part and a back pressure part.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A bonding device comprising:
a lower electrostatic chuck;
an upper electrostatic chuck disposed above the lower electrostatic chuck;
an elastic part disposed above the upper electrostatic chuck;
a first shaft disposed on the upper electrostatic chuck and disposed in a space which is defined inside the elastic part;
a first plate disposed on the first shaft and the elastic part;
a bracket disposed on the first plate;
a first cylinder disposed on the bracket;
a guide rod disposed on the first plate; and
a second cylinder disposed adjacent to the guide rod in a horizontal direction and connected to an upper end portion of the guide rod.

2. The bonding device of claim 1, further comprising:
a support plate disposed above the first plate and including a hole, wherein
the first cylinder is disposed on the support plate and extends toward the bracket,
the second cylinder is disposed on the support plate, and
the guide rod extends above the support plate through the hole of the support plate.

3. The bonding device of claim 2, wherein the first cylinder comprises:
a first body disposed on the support plate; and
a first movable rod connected to a lower part of the first body, extending below the support plate, and disposed on the bracket, and
the first movable rod is movable vertically.

4. The bonding device of claim 3, wherein the first movable rod is separated from the bracket and is in contact with an upper surface of the bracket.

5. The bonding device of claim 3, further comprising:
a support pillar adjacent to a side of the support plate; and
a vertical moving part connected to a side of the support plate and the support pillar and moving in a vertical direction.

6. The bonding device of claim 5, wherein
in case that process objects disposed on an upper surface of the lower electrostatic chuck and a lower surface of the upper electrostatic chuck are bonded to each other,
the vertical moving part is movable in a downward direction by a first distance, and
the first movable rod is movable toward the first body by a second distance shorter than the first distance.

7. The bonding device of claim 2, wherein the second cylinder comprises:
a second body disposed on the support plate; and
a second movable rod connected to an upper part of the second body, extending upward, and connected to an upper end portion of the guide rod, and
the second movable rod is movable vertically.

8. The bonding device of claim 7, further comprising:
a connection bar connected to the upper end portion of the guide rod and an upper end portion of the second movable rod.

9. The bonding device of claim 1, wherein
the first cylinder is provided in plurality,
the second cylinder is provided in plurality,
the plurality of first cylinders are arranged in a first direction, and
the plurality of second cylinders are spaced apart from the plurality of first cylinders in a second direction intersecting the first direction, and are arranged in the first direction.

10. The bonding device of claim 9, wherein
the guide rod is provided in plurality,
the plurality of guide rods are arranged in the first direction and are spaced apart from the plurality of first cylinders in the second direction, and
the plurality of second cylinders are disposed between the plurality of guide rods.

11. The bonding device of claim 1, further comprising:
a second shaft disposed under the lower electrostatic chuck; and
a second plate disposed under the second shaft.

12. The bonding device of claim 1, wherein
an upper surface of the lower electrostatic chuck has a concave curved surface, and
a lower surface of the upper electrostatic chuck has a convex curved surface.

13. The bonding device of claim 12, wherein
a display module is disposed on the upper surface of the lower electrostatic chuck, and
a window is disposed on the lower surface of the upper electrostatic chuck.

14. The bonding device of claim 1, wherein the elastic part provides an elastic force to the first plate and the lower electrostatic chuck in a vertical direction.

15. A bonding device comprising:
a lower electrostatic chuck;
an upper electrostatic chuck disposed above the lower electrostatic chuck;
an elastic part disposed above the upper electrostatic chuck;
a first shaft disposed on the upper electrostatic chuck and disposed in a space which is defined inside the elastic part;
a first plate disposed on the first shaft and the elastic part;
a bracket disposed on the first plate;
a first cylinder including:
a first body disposed on the bracket, and
a first movable rod extending from the first body toward the bracket and being in contact with the bracket;
a guide rod disposed on the first plate; and
a second cylinder disposed adjacent to the guide rod in a horizontal direction and connected to an upper end portion of the guide rod.

16. The bonding device of claim 15, wherein the first movable rod is separated from the bracket and is in contact with an upper surface of the bracket.

17. The bonding device of claim 15, further comprising:
a support plate disposed above the first plate, wherein
the second cylinder includes:
a second body disposed on the support plate, and
a second movable rod connected to an upper part of the second body and extending upward, and connected to an upper end portion of the guide rod, and
the second movable rod is movable vertically.

18. A bonding device comprising:
a lower electrostatic chuck;
an upper electrostatic chuck disposed above the lower electrostatic chuck;
an elastic part disposed above the upper electrostatic chuck;
a first shaft disposed on the upper electrostatic chuck and disposed in a space which is defined inside the elastic part;
a first plate disposed on the first shaft and the elastic part;
a bracket disposed on the first plate;
a first cylinder disposed on the bracket;
a guide rod disposed on the first plate;
a second cylinder disposed adjacent to the guide rod in a horizontal direction; and
a connection bar connected to an upper end portion of the guide rod and an upper end portion of the second cylinder.
